(19) United States
(12) Patent Application Publication
(10) Pub. No.: US 2024/0291136 A1
(43) Pub. Date: Aug. 29, 2024

(54) Three-dimensional Heterogeneous Integrated Millimeter-wave System Package Structure

(71) Applicant: SOUTH CHINA UNIVERSITY OF TECHNOLOGY, Guangzhou (CN)

(72) Inventors: Haoshen ZHU, Guangzhou (CN); Zhirui CHEN, Guangzhou (CN); Wenjie FENG, Guangzhou (CN); Quan XUE, Guangzhou (CN)

(21) Appl. No.: 18/658,201

(22) Filed: May 8, 2024

(30) Foreign Application Priority Data
Jul. 25, 2023 (CN) 202310917977.9

(51) Int. Cl. H01Q 1/22; H01L 23/00; H01L 23/538; H01L 25/10; H01Q 1/02; H04B 1/40

(52) U.S. Cl. CPC H01Q 1/2283; H01L 23/5385; H01L 24/16; H01L 25/105; H01Q 1/02; H01L 2224/16145; H01L 2224/16227; H04B 1/40

(57) ABSTRACT

The present invention provides a three-dimensional heterogeneous integrated millimeter-wave system package structure, which is composed of an upper antenna board and a lower chip carrier board. The upper antenna board has an integrated structure with an antenna in package and a feed network arranged inside, the lower chip carrier board has a modular structure provided with a first chipset and a second chipset which are heterogeneous integrated, and each chipset comprises a plurality of chips of the same or different processes.

### TECHNICAL FIELD

The present invention relates to the technical field of chip packaging, in particular to a three-dimensional heterogeneous integrated millimeter-wave system package structure.

### BACKGROUND

With the rapid development of the fifth generation mobile communication technology (5G), the widely used frequency spectra below 6 GHz cannot meet people's demand for higher data rates. The millimeter-wave (mmW) band can provide a wider absolute frequency bandwidth, which is very attractive for application at ultra-high data rates. However, the prominent air loss (attenuation) poses a great challenge to millimeter-wave wireless communication. In this case, the beamforming technology enabled by a large-scale phased array architecture is the key to overcome this challenge and maintain the radio coverage. Furthermore, the loss of interconnection between antennas and millimeter-wave integrated circuits (ICs) is also much higher than that of conventional systems below 6 GHz at millimeter-wave frequencies, so as to reduce the noise figure (NF) and the power added efficiency (PAE) of the systems.

Therefore, the antennas of the phased array architecture are integrated in the package so as to further reduce the loss of interconnection between the antennas and the millimeter-wave integrated circuits, that is Antenna in Package (AiP) technology. The AiP and different chips are integrated in one package structure, which further meets the requirements of high integration level, low loss and high reliability of the current radio frequency systems.

A variety of radio frequency package structures are available at present, but have the following disadvantages:

The whole package structure does not contain a complete millimeter-wave system module: only the main control chip and radio frequency front-end chips are included, or only radio frequency front-end chips and antennas are included, and the main control chip, radio frequency front-end chips and antennas are rarely integrated in one package structure; most of the package structures are two-dimensional planar package structures, and the number of chips that can be packaged is small; the package of antennas and chips is integral, which increases the testing difficulty and reduces the package yield; once integrated into a package structure, antennas are not replaceable, and in case of replacement, the antennas need to be redesigned; and for the package of large-scale phased array and millimeter-wave integrated circuits, most of the circuits are packaged and then spliced to form a large-scale phased array system, which will inevitably produce a certain phase difference between channels.

### SUMMARY

The purpose of the present invention is to provide a three-dimensional heterogeneous integrated millimeter-wave system package structure, which integrates antennas, radio frequency control chips and radio frequency front-end chips to carry out integrated production design, thus improving the integration level and the package yield and meeting the package requirements of multi-channel millimeter-wave phased arrays for communication or radar applications.

To achieve the above purpose, the present invention provides the following solution:
A three-dimensional heterogeneous integrated millimeter-wave system package structure, composed of an upper antenna board and a lower chip carrier board; a gap is arranged between the upper antenna board and the lower chip carrier board which are connected through solder balls; the upper antenna board has an integrated structure with an AiP and a feed network arranged inside, the lower chip carrier board has a modular structure provided with a first chipset and a second chipset, the second chipset is located under the first chipset, the first chipset comprises a plurality of first chips, the second chipset comprises a plurality of second chips, the first chips and the second chips are heterogeneous chips fabricated by different semiconductor technologies, and the surfaces with active devices of the first chips and the second chips are face-to-face but are staggered in the vertical direction;
The lower chip carrier board is composed of an upper redistribution layer (RDL), a core layer and a lower RDL stacked successively from top to bottom; and the upper antenna board is provided with a plurality of vertical metalized vias and connected to the upper RDL through solder balls/bumps, and the upper RDL, the core layer and the lower RDL are respectively provided with a plurality of metalized vias through which any-layer interconnection is realized;
The first chips are electrically connected with the second chips through the metalized vias and/or solder balls/bumps by means of metal interconnection;
The upper antenna board is made by a planar circuit/package process.

Further, the first chipset is arranged on the upper surface of the lower chip carrier board, the second chipset is embedded in the core layer of the lower chip carrier board and located between the upper RDL and the lower RDL, and the lower surfaces of the second chips are provided with metalized vias and connected with the solder balls/bumps.

Further, the first chipset is arranged on the upper surface of the lower chip carrier board, and the second chipset is arranged on the lower surface of the lower chip carrier board; and the lower surfaces of the first chips are provided with solder balls/bumps which are connected to the upper RDL, the upper surfaces of the second chips are provided with solder balls/bumps which are connected to the lower RDL, the lower surfaces of the second chips are provided with tooth heat sink for heat dissipation, the bottom of the millimeter-wave system package structure is connected with a printed circuit board (PCB) board, and the PCB board is provided with an open cavity for accommodating the tooth heat sink.

Further, the lower surface of the upper antenna board is provided with a groove, the first chipset is arranged in the groove, the lower surfaces of the first chips are the surfaces with active devices of the first chips, the lower surfaces of the first chips are provided with solder balls/bumps, the upper surfaces of the second chips are the surfaces with active devices of the second chips, and the upper surfaces of the second chips are provided with metalized vias and solder balls/bumps which are connected with the solder balls/bumps arranged on the lower surfaces of the first chips.

Further, one first chip is arranged and is a silicon-based radio frequency control chip, and correspondingly, one groove is arranged and located in the central position of the lower surface of the upper antenna board; and a plurality of second chips are arranged and are compound semiconductor radio frequency front-end chips.

Further, a plurality of first chips are arranged, comprising one silicon-based radio frequency control chip and a plurality of power management units (PMUs), and correspondingly, a plurality of grooves are arranged, wherein one groove is located in the central position of the lower surface of the upper antenna board for arranging one silicon-based radio frequency control chip, and the remaining grooves are used for arranging the PMUs and arranged around the silicon-based radio frequency control chip.

Further, the first chipset is arranged in the gap between the upper antenna board and the lower chip carrier board, the diameter of the solder balls between the upper antenna board and the lower chip carrier board is greater than the thickness of the first chips, and the bottoms of the first chips are provided with solder balls/bumps which are connected to the upper RDL; and the upper surfaces of the second chips are provided with metalized vias which are connected with the solder balls/bumps at the bottoms of the first chips.

Further, the first chipset is embedded in the core layer of the lower chip carrier board, the second chipset is arranged on the lower surface of the lower chip carrier board, the upper surfaces of the second chips are provided with solder balls/bumps which are connected to the lower RDL, and the first chips and the second chips are electrically connected through the solder balls/bumps directly; and the lower surfaces of the second chips are provided with tooth heat sink for heat dissipation, the bottom of the millimeter-wave system package structure is connected with a PCB board, and the PCB board is provided with an open cavity for accommodating the tooth heat sink.

Further, the upper surface of the lower chip carrier board is provided with surface mounted devices (SMDs); and the lower chip carrier board is made by superimposing a plurality of different material layers.

Further, the first chips are silicon-based radio frequency control chips which are fabricated by a CMOS, SiGe BiCMOS or SOI technology; and the second chips are compound semiconductor radio frequency front-end chips which are fabricated by a GaAs, GaN or InP technology.

According to specific embodiments provided by the present invention, the three-dimensional heterogeneous integrated millimeter-wave system package structure provided by the present invention discloses the following technical effects:
(1) High integration level: the three-dimensional package structure makes the area of chips larger than the package area, the whole structure contains a complete radio frequency system, including but not limited to antennas, radio frequency front-end chips and main control chip, and meanwhile, passive devices also can be integrated to achieve better electrical performance;
(2) Excellent radio frequency performance: the radio frequency channels demand high consistency, the number of channels in a large-scale antenna array is large, and the antenna arrays integrated in a single module rather than the tile-type multi-module design can avoid the problem of phase difference between channels caused by module splicing; and meanwhile, the use of low-loss media can ensure the quality of signals during transmission;
(3) High flexibility: the package structure can be applied to phased array systems of different scales, where the antennas need to be designed according to the phased array systems of different scales, and the lower chip carrier board only needs to change the corresponding number of modules to match the phased array system of an appropriate scale;
(4) High product yield: the package product is divided into the upper antenna board of integrated design and the lower chip carrier board of the multi-module radio frequency front-end chipset, and thus can be inspected part by part; and meanwhile, the antennas of integrated design have stable process and simple structure, and if a problem is detected from the front-end chipset in the lower chip carrier board, only the corresponding module needs to be replaced, so the whole package structure can ensure a high yield.

### DESCRIPTION OF DRAWINGS

To more clearly describe the technical solutions in the embodiments of the present invention or in prior art, the drawings required to be used in the embodiments will be simply presented below. Apparently, the drawings in the following description are merely some embodiments of the present invention, and for those skilled in the art, other drawings can also be obtained according to these drawings without contributing creative labor.

FIG. 1-1 is a structural schematic diagram of embodiment 1 of a three-dimensional heterogeneous integrated millimeter-wave system package structure of the present invention;

FIG. 1-2 is another structural schematic diagram of embodiment 1 of a three-dimensional heterogeneous integrated millimeter-wave system package structure of the present invention;

FIG. 2 is a structural schematic diagram of embodiment 2 of a three-dimensional heterogeneous integrated millimeter-wave system package structure of the present invention;

FIG. 3 is a structural schematic diagram of embodiment 3 of a three-dimensional heterogeneous integrated millimeter-wave system package structure of the present invention;

FIG. 4 is a structural schematic diagram of embodiment 4 of a three-dimensional heterogeneous integrated millimeter-wave system package structure of the present invention;

FIG. 5 is a structural schematic diagram of embodiment 5 of a three-dimensional heterogeneous integrated millimeter-wave system package structure of the present invention;

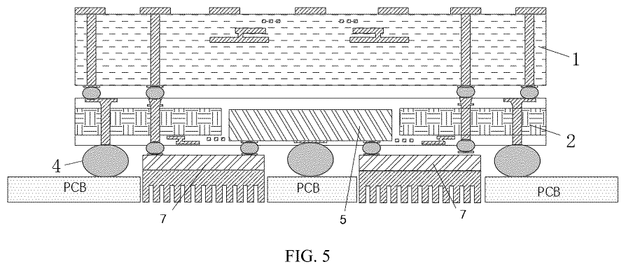

Reference Signs: 1. upper antenna board; 2. core layer; 3. AiP; 4. solder ball; 5. first chip; 5-1. silicon-based millimeter-wave chip; 5-2. PMU; 6. metalized via; 7. second chip; 8. upper RDL; 9. lower RDL; 10. SMD; 11. integrated passive device; 12. shielding copper via; and 13. shielding copper layer.

### DETAILED DESCRIPTION

The technical solution in the embodiments of the present invention will be clearly and fully described below in combination with the drawings in the embodiments of the present invention. Apparently, the described embodiments are merely part of the embodiments of the present invention, not all of the embodiments. Based on the embodiments in the present invention, all other embodiments obtained by those ordinary skilled in the art without contributing creative labor will belong to the protection scope of the present invention.

The purpose of the present invention is to provide a three-dimensional heterogeneous integrated millimeter-wave system package structure, which integrates antennas, radio frequency control chips and radio frequency front-end chips to carry out integrated production design, thus improving the integration level and the package yield and meeting the package requirements of multi-channel millimeter-wave phased arrays for communication or radar applications.

To make the above-mentioned purpose, features and advantages of the present invention more clear and understandable, the present invention will be further described below in detail in combination with the drawings and specific embodiments.

The three-dimensional heterogeneous integrated millimeter-wave system package structure provided by the present invention is composed of an upper antenna board 1 and a lower chip carrier board; a gap is arranged between the upper antenna board 1 and the lower chip carrier board which are connected through solder balls; and the upper antenna board 1 has an integrated structure with an AiP 3 and a feed network arranged inside, the lower chip carrier board has a modular structure provided with a first chipset and a second chipset, the second chipset is located under the first chipset, the first chipset comprises a plurality of first chips 5, the second chipset comprises a plurality of second chips 7, the first chips 5 and the second chips 7 are heterogeneous chips fabricated by different semiconductor technologies, and the surfaces with active devices of the first chips 5 and the second chips 7 are face-to-face but are staggered in the vertical direction;

The lower chip carrier board is composed of an upper RDL 8, a core layer 2 and a lower RDL 9 stacked successively from top to bottom; and the upper antenna board 1 is provided with a plurality of vertical metalized vias and connected to the upper RDL 8 through solder balls/bumps, and the upper RDL 8, the core layer 2 and the lower RDL 9 are respectively provided with a plurality of metalized vias through which any-layer interconnection is realized;

The first chips 5 are electrically connected with the second chips 7 through the metalized vias and/or solder balls/bumps by means of metal interconnection.

Exemplarily, the first chips 5 are silicon-based radio frequency control chips which are fabricated by a CMOS, SiGe BiCMOS or SOI technology; and the second chips 7 are compound semiconductor radio frequency front-end chips which are fabricated by a GaAs, GaN or InP technology.

The upper antenna board 1 is made by a planar circuit/package process, including but not limited to low temperature co-fired ceramic (LTCC) and high density interconnect (HDI).

The three-dimensional heterogeneous integrated millimeter-wave system package structure is characterized by being divided into an upper part and a lower part, wherein the upper antenna board 1 of the upper part comprises a large-scale AiP that does not need to be divided; and the lower chip carrier board of the lower part is composed of a plurality of combinable package substrates, each package substrate comprises a plurality of heterogeneous first chips 5 and second chips 7 which can be a plurality of control silicon-based chips and radio frequency front-end chips.

The large-scale AiP of the upper part can be made of LTCC, or made of HDI substrates by means of lamination, or made of glass. As long as the pin of the AiP can be compatible with the bonding pad of the lower chip carrier board, the types of the antennas can be varied. If the upper antenna board is made through a relatively simple process without arranging a cavity, large-sized solder balls are required to prop up a certain height to accommodate chips; and the upper antenna board also can be provided with a cavity to accommodate the chips, and meanwhile, smaller solder balls are used to reduce the whole package height. The upper antenna board also can be provided with RDLs and integrated passive devices (IPDs) inside to achieve the functions of filtering and decoupling.

The structure of the lower chip carrier board of the lower part is symmetrical about the middle core layer 2, and a thin film medium and a metal conductor are made on the upper and lower surfaces of the core layer through the laminate technology. The thickness and material of the medium layer can be adjusted according to the actual situations, and the medium layer can be made of a variety of materials to form the laminated structure. III-V chips can be embedded in the middle core layer 2, the silicon-based chips are inverted on the upper surface of the lower chip carrier board, the signals of the silicon-based chips are led to the surface of the substrate through the solder balls or micro-bumps for electrical connection, and the bottoms of the III-V chips transfer heat to the solder balls through the metalized vias to dissipate heat. SMDs such as capacitor can be welded on the surface of the lower chip carrier board.

The III-V chips also can be arranged under the lower chip carrier board for welding, the silicon-based chips are arranged on the upper surface of the lower chip carrier board, the bottoms of the III-V chips dissipate heat through the tooth heat sink, and the PCB connected with the chips needs to be provided with a cavity for accommodating the tooth heat sink. Exemplarily, the silicon-based chips can be embedded in the lower chip carrier board and directly connected with the III-V chips to achieve the minimum distance of electrical connection and reduce the difficulty in antenna production.

The number of the silicon-based chips can be more than one, one silicon-based millimeter-wave chip and a plurality of PMUs can be flip-chip mounted on the upper surface of the lower chip carrier board, and the plurality of silicon-based chips can be shielded to prevent electromagnetic interference. Shielding layers can be composed of shielding copper layers and shielding copper vias.

The edge of the lower chip carrier board of each module is provided with a chute to facilitate combination of a plurality of modules. The lower surface of the lower chip carrier board is welded with large-sized solder balls which will be electrically connected with the PCB.

The working principle of the three-dimensional heterogeneous integrated millimeter-wave system package structure is as follows:
Signal reception: signals are received through the AiP in the upper antenna board, transmitted to the radio frequency front-end chips in the lower chip carrier board for low noise amplification, and then transmitted to the silicon-based millimeter-wave chip for processing;
Signal transmission: the signal of the silicon-based millimeter-wave chip is transmitted to the radio frequency front-end chips for power amplification, and then transmitted to the AiP for transmission into free space;
Power supply: the lower chip carrier board is connected with the PCB by the bottom solder balls of the millimeter-wave system package structure, and the PCB supplies direct current to each chip through the solder balls.

The positions of the first chips and the second chips are arranged in a diversified manner, thus forming various types of three-dimensional heterogeneous integrated millimeter-wave system package structures, as detailed in the following embodiments.

### Embodiments 1

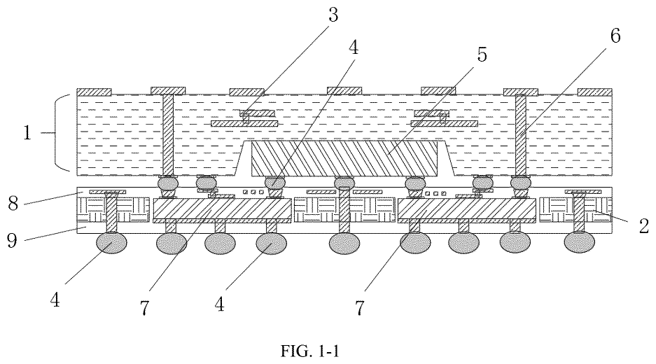

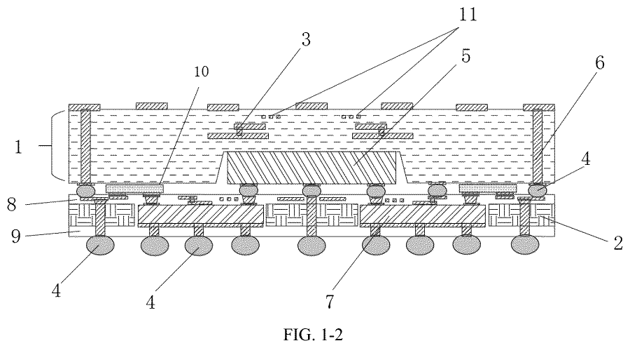

As shown in FIG. 1-1, the first chipset is arranged on the upper surface of the lower chip carrier board, the second chipset is embedded in the core layer 2 of the lower chip carrier board and located between the upper RDL 8 and the lower RDL 9, and the lower surfaces of the second chips 7 are provided with metalized vias and connected with the solder balls. The second chips 7 can transfer heat to the solder balls through the metalized vias for heat dissipation, and also can be matched with the solder balls through the metalized vias for electrical connection.

The lower surface of the upper antenna board 1 is provided with a groove, the first chipset is arranged in the groove, the lower surfaces of the first chips 5 are the surfaces with active devices of the first chips 5, the lower surfaces of the first chips 5 are provided with solder balls/bumps, the upper surfaces of the second chips 7 are the surfaces with active devices of the second chips 7, and the upper surfaces of the second chips 7 are provided with metalized vias and solder balls/bumps which are connected with the solder balls arranged on the lower surfaces of the first chips 5.

Specifically, a groove is arranged in the central position of the lower surface of the upper antenna board 1, one first chip 5 is arranged in the groove, the bottoms of the first chips 5 are provided with solder balls/bumps 4, the upper surfaces of the second chips 7 are provided with metalized vias, and the first chips 5 and the second chips 7 are matched and connected through the metalized vias and the solder balls/bumps. The first chips 5 can be silicon-based millimeter-wave chips, and the second chips 7 can be III-V chips.

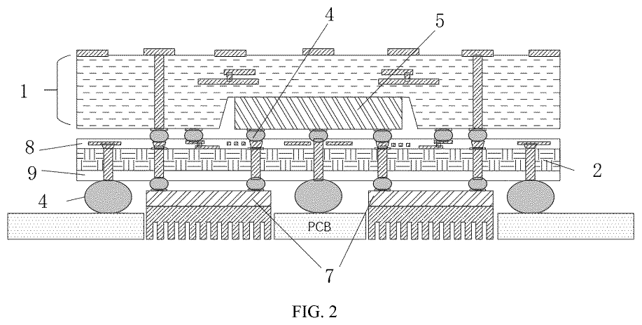

Exemplarily, as shown in FIG. 1-2, the upper surface of the lower chip carrier board also can be provided with SMDs 10; and the lower chip carrier board is made by superimposing a plurality of different material layers.

The upper large-scale AiP contained in the three-dimensional heterogeneous integrated millimeter-wave system package structure in embodiment 1 is made of LTCC in an integrated mode, comprising 256 antenna units; and the lower chip carrier board is composed of eight package substrate modules which are made of composite materials by stacking. Every four antenna units are controlled by one III-V GaAs FEM chip, and every eight GaAS FEMs are interconnected by one 8-channel silicon-based millimeter-wave chip, which together form a modular combination of the lower chip carrier board at the lower layer.

For the upper antenna board, the lower surface needs to be provided with a cavity to accommodate the silicon-based millimeter-wave chip, and a feed port also needs to be designed according to the signal port of the GaAS FEM of the lower chip carrier board. IPDs 11 are arranged in the antenna layer to filter the antenna.

The lower chip carrier board has eight layers of metal, which are symmetrically designed vertically with the core layer as the center and filled with Ajinomoto build-up film (ABF), prepreg (PP) and liquid crystal polymer (LCP) in sequence from inside to outside as the media of different layers. The GaAs FEMs are embedded in the core layer, and the signal passes through the ABF medium through the vias from the fourth layer to reach the third metal RDL. The metallized back surfaces of the FEMs are led through the metalized vias to the bottom solder balls for heat dissipation. Because the ABF material can be made relatively thin, relatively thin vias can be used, and it is very effective for signal lead-out of narrow-pitch bonding pads; the medium between the second and third layers is PP, which has good high-frequency performance and filling effect; and the medium between the first and second layers is LCP, whose excellent high-frequency performance can support the high-frequency signal routing of the surface layer. The signal is led from the core layer to the surface layer with a total length of 4.82 mm and the insertion loss of −1.5 dB@76 GHz.

The silicon-based millimeter-wave chip is electrically connected with the upper surface of the package substrate using the gold-gold bonding process through 90 um gold balls; and the lower surface of the package substrate is electrically connected with the PCB through 350 um solder balls. Meanwhile, the back surfaces of the GaAs chips are metallized and can be led through the metalized vias to the solder balls of the lower surface of the package substrate, so as to achieve the purpose of heat dissipation of the chips. In terms of power supply of the GaAs chips, a small capacitor surface welding device is welded to the surface of the package substrate to reduce DC ripples.

A fixed frame is used for module splicing on the lower chip carrier board. The fixed frame is slightly thicker than the substrate of the module so that the edge of the module can be embedded in the fixed frame.

### Embodiment 2

As shown in FIG. 2, the main difference from embodiment 1 is that: the radio frequency front-end chips are not embedded in the core layer of the lower chip carrier board, but are welded to the bottom of the lower chip carrier board, and the overall structure is supported by larger solder balls.

Specifically, the first chipset is arranged on the upper surface of the lower chip carrier board, and the second chipset is arranged on the lower surface of the lower chip carrier board; and the lower surfaces of the first chips 5 are provided with solder balls/bumps which are connected to the upper RDL 8, the upper surfaces of the second chips 7 are provided with solder balls/bumps which are connected to the lower RDL 9, the lower surfaces of the second chips 7 are provided with tooth heat sink for heat dissipation, the bottom of the millimeter-wave system package structure is connected with a PCB board, and the PCB board is provided with an open cavity for accommodating the tooth heat sink.

A groove is arranged in the central position of the lower surface of the upper antenna board 1, one first chip 5 is arranged in the groove, the bottoms of the first chips 5 are provided with solder balls/bumps, and the upper surfaces of the second chips 7 are provided with metalized vias which are connected with the solder balls/bumps at the bottoms of the first chips 5. The first chips 5 can be silicon-based millimeter-wave chips, and the second chips 7 can be III-V chips. The second chips 7 and the first chips 5 are electrically connected through the metalized vias.

### Embodiment 3

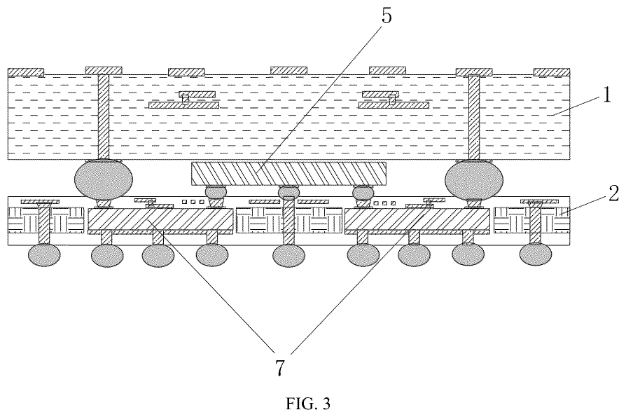

As shown in FIG. 3, embodiment 3 is similar to embodiment 1, except that the upper antenna board 1 is not provided with a cavity, but is propped up to a certain height through large solder balls to accommodate the chips.

Specifically, the second chips 7 are embedded in the core layer 2 of the lower chip carrier board, the lower surfaces of the second chips 7 are provided with metalized vias and connected with solder balls, the second chips 7 transfer heat to the solder balls through the metalized vias for heat dissipation, and the metalized vias can be also used for electrical connection to different layers.

The first chips 5 are arranged in the gap between the upper antenna board 1 and the lower chip carrier board, the diameter of the large solder balls between the upper antenna board 1 and the lower chip carrier board is greater than the thickness of the first chips 5, and the bottoms of the first chips 5 are provided with solder balls/bumps which are connected to the upper RDL 8; and the upper surfaces of the second chips 7 are provided with metalized vias which are connected with the solder balls/bumps at the bottoms of the first chips 5.

Compared with embodiment 1, the present embodiment will be implemented more simply and more conveniently in terms of process.

### Embodiment 4

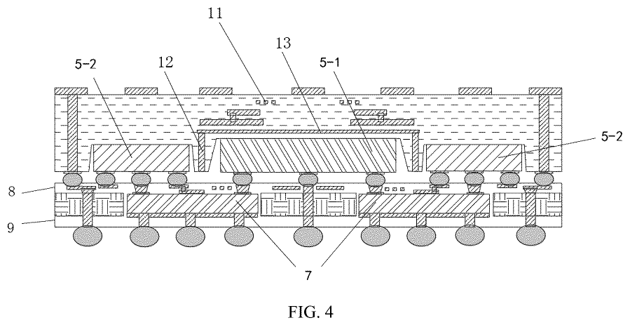

As shown in FIG. 4, embodiment 4 is similar to embodiment 1, except that the first chips 5 on the surface of the lower chip carrier board include not only silicon-based millimeter-wave chips, but also PMUs for DC power supply. The PMUs are used for providing DC bias voltage for each radio frequency front-end chip and adjusting the bias voltage of the radio frequency front-end chips through the control command received from the silicon-based millimeter-wave chip to achieve the purpose of controlling the gain of the radio frequency front-end chips.

Because a plurality of different silicon-based chips exist at the same level, it is necessary to add electromagnetic shielding layers around the silicon-based millimeter-wave chip used as the main control chip to prevent electromagnetic interference. Shielding copper vias 12 arranged closely are added around the main control chip, and a metal layer such as shielding copper layer 13 is added at the bottom of the chip, which together form electromagnetic shielding layers.

Specifically, the second chips 7 are embedded in the lower chip carrier board, the lower surfaces of the second chips 7 are provided with metalized vias and connected with solder balls, the second chips 7 transfer heat to the solder balls through the metalized vias for heat dissipation, and the metalized vias can be also used for electrical connection to different layers.

The lower surface of the upper antenna board 1 is provided with a groove, the first chips 5 are arranged in the groove, the bottoms of the first chips 5 are provided with solder balls/bumps, and the upper surfaces of the second chips 7 are provided with metalized vias which are connected with the solder balls/bumps at the bottoms of the first chips 5. A plurality of first chips 5 are arranged, comprising one silicon-based millimeter-wave chip 5-1 and a plurality of PMUs 5-2, and correspondingly, a plurality of grooves are arranged, wherein one groove is located in the central position of the lower surface of the upper antenna board for arranging one silicon-based millimeter-wave chip 5-1, and the remaining grooves are used for arranging the PMUs 5-2 and arranged around the silicon-based millimeter-wave chip 5-1. Electromagnetic shielding layers are arranged between the plurality of first chips.

### Embodiment 5

Embodiment 5 is similar to embodiment 2, except that the silicon-based millimeter-wave chip is embedded in the core layer 2 of the lower chip carrier board, so the upper antenna board 1 does not need to be provided with a cavity, and the upper antenna board 1 also can adopt small solder balls. The radio frequency front-end chips and the silicon-based millimeter-wave chip can be electrically connected directly through the solder balls/bumps to achieve the minimum interconnection distance, so as to obtain better high-frequency electrical performance.

Specifically, the first chipset is embedded in the core layer 2 of the lower chip carrier board, the second chipset is arranged on the lower surface of the lower chip carrier board, the upper surfaces of the second chips 7 are provided with solder balls/bumps which are connected to the lower RDL 9, and the first chips 5 and the second chips 7 are electrically connected through the solder balls/bumps directly; and the lower surfaces of the second chips 7 are provided with tooth heat sink for heat dissipation, the bottom of the millimeter-wave system package structure is connected with a PCB board, and the PCB board is provided with an open cavity for accommodating the tooth heat sink.

To sum up, the three-dimensional heterogeneous integrated millimeter-wave system package structure provided by the present invention (1) solves the problem of low integration level of radio frequency package: the antennas, the main control chip and the front-end chips are integrated; (2) solves the problem of phase consistency of large-scale antennas: the antennas are not disassembled and reassembled, but are directly produced in an integrated mode; (3) solves the problem that different antennas need different package designs: once-through design can meet the package requirements of different antennas; (4) solves the problem of high loss of interconnection between chips: the system with high integration level reduces the interconnection length, while the use of superior high-frequency materials further reduces the loss of interconnection; and (5) solves the problems of low package yield and high cost of a plurality of chips: the package structure is divided into an upper integrated antenna without chips and a lower multi-module package substrate with chips, and if a chip is detected with a problem, only the chip with a problem needs to be replaced rather than the whole package structure.

Specific individual cases are applied herein for elaborating the principle and embodiments of the present invention. The illustration of the above embodiments is merely used for helping to understand the method and the core thought of the present invention. Meanwhile, for those ordinary skilled in the art, specific embodiments and the application scope may be changed in accordance with the thought of the present invention. In conclusion, the contents of the description shall not be interpreted as a limitation to the present invention.

1. A three-dimensional heterogeneous integrated millimeter-wave system package structure, composed of an upper antenna board and a lower chip carrier board; a gap is arranged between the upper antenna board and the lower chip carrier board which are connected through solder balls; and the upper antenna board has an integrated structure with an antenna in package (AiP) and a feed network arranged inside, the lower chip carrier board has a modular structure provided with a first chipset and a second chipset, the second chipset is located under the first chipset, the first chipset comprises a plurality of first chips, the second chipset comprises a plurality of second chips, the first chips and the second chips are heterogeneous chips fabricated by different semiconductor technologies, and the surfaces with active devices of the first chips and the second chips are face-to-face but are staggered in the vertical direction;
the lower chip carrier board is composed of an upper redistribution layer (RDL), a core layer and a lower RDL stacked successively from top to bottom; and the upper antenna board is provided with a plurality of vertical metalized vias and connected to the upper RDL through solder balls/bumps, and the upper RDL, the core layer and the lower RDL are respectively provided with a plurality of metalized vias through which any-layer interconnection is realized;
the first chips are electrically connected with the second chips through the metalized vias and/or solder balls/bumps by means of metal interconnection;
the upper antenna board is made by a planar circuit/package process;
the first chipset is arranged on the upper surface of the lower chip carrier board, the second chipset is embedded in the core layer of the lower chip carrier board and located between the upper RDL and the lower RDL, and the lower surfaces of the second chips are provided with metalized vias and connected with the solder balls/bumps;
the lower surface of the upper antenna board is provided with a groove, the first chipset is arranged in the groove, the lower surfaces of the first chips are the surfaces with active devices of the first chips, the lower surfaces of the first chips are provided with solder balls/bumps, the upper surfaces of the second chips are the surfaces with active devices of the second chips, and the upper surfaces of the second chips are provided with metalized vias and solder balls/bumps which are connected with the solder balls/bumps arranged on the lower surfaces of the first chips;
a plurality of first chips are arranged, comprising one silicon-based radio frequency control chip and a plurality of power management units (PMUs), and correspondingly, a plurality of grooves are arranged, wherein one groove is located in the central position of the lower surface of the upper antenna board for arranging one silicon-based radio frequency control chip, and the remaining grooves are used for arranging the PMUs and arranged around the silicon-based radio frequency control chip.

2. The three-dimensional heterogeneous integrated millimeter-wave system package structure according to claim 1, wherein the upper surface of the lower chip carrier board is provided with surface mounted devices (SMDs); and the lower chip carrier board is made by superimposing a plurality of different material layers.

3. The three-dimensional heterogeneous integrated millimeter-wave system package structure according to claim 1, wherein the first chips are silicon-based radio frequency control chips which are fabricated by a CMOS, SiGe BiCMOS or SOI technology; and the second chips are compound semiconductor radio frequency front-end chips which are fabricated by a GaAs, GaN or InP technology.

4. A three-dimensional heterogeneous integrated millimeter-wave system package structure, composed of an upper antenna board and a lower chip carrier board; a gap is arranged between the upper antenna board and the lower chip carrier board which are connected through solder balls; and the upper antenna board has an integrated structure with an AiP and a feed network arranged inside, the lower chip carrier board has a modular structure provided with a first chipset and a second chipset, the second chipset is located under the first chipset, the first chipset comprises a plurality of first chips, the second chipset comprises a plurality of second chips, the first chips and the second chips are heterogeneous chips fabricated by different semiconductor technologies, and the surfaces with active devices of the first chips and the second chips are face-to-face but are staggered in the vertical direction;
the lower chip carrier board is composed of an upper RDL, a core layer and a lower RDL stacked successively from top to bottom; and the upper antenna board is provided with a plurality of vertical metalized vias and connected to the upper RDL through solder balls/bumps, and the upper RDL, the core layer and the lower RDL are respectively provided with a plurality of metalized vias through which any-layer interconnection is realized;
the first chips are electrically connected with the second chips through the metalized vias and/or solder balls/bumps by means of metal interconnection;
the upper antenna board is made by a planar circuit/package process;
the first chipset is arranged on the upper surface of the lower chip carrier board, the second chipset is embedded in the core layer of the lower chip carrier board and located between the upper RDL and the lower RDL, and the lower surfaces of the second chips are provided with metalized vias and connected with the solder balls/bumps;
the first chipset is arranged in the gap between the upper antenna board and the lower chip carrier board, the diameter of the solder balls between the upper antenna board and the lower chip carrier board is greater than the thickness of the first chips, and the bottoms of the first chips are provided with solder balls/bumps which are connected to the upper RDL; and the upper surfaces of the second chips are provided with metalized vias which are connected with the solder balls/bumps at the bottoms of the first chips.

5. The three-dimensional heterogeneous integrated millimeter-wave system package structure according to claim 4, wherein the upper surface of the lower chip carrier board is provided with SMDs; and the lower chip carrier board is made by superimposing a plurality of different material layers.

6. The three-dimensional heterogeneous integrated millimeter-wave system package structure according to claim 4, wherein the first chips are silicon-based radio frequency control chips which are fabricated by a CMOS, SiGe BiCMOS or SOI technology; and the second chips are compound semiconductor radio frequency front-end chips which are fabricated by a GaAs, GaN or InP technology.

7. A three-dimensional heterogeneous integrated millimeter-wave system package structure, composed of an upper antenna board and a lower chip carrier board; a gap is arranged between the upper antenna board and the lower chip carrier board which are connected through solder balls; and the upper antenna board has an integrated structure with an AiP and a feed network arranged inside, the lower chip carrier board has a modular structure provided with a first chipset and a second chipset, the second chipset is located under the first chipset, the first chipset comprises a plurality of first chips, the second chipset comprises a plurality of second chips, the first chips and the second chips are heterogeneous chips fabricated by different semiconductor technologies, and the surfaces with active devices of the first chips and the second chips are face-to-face but are staggered in the vertical direction;
the lower chip carrier board is composed of an upper RDL, a core layer and a lower RDL stacked successively from top to bottom; and the upper antenna board is provided with a plurality of vertical metalized vias and connected to the upper RDL through solder balls/bumps, and the upper RDL, the core layer and the lower RDL are respectively provided with a plurality of metalized vias through which any-layer interconnection is realized;
the first chips are electrically connected with the second chips through the metalized vias and/or solder balls/bumps by means of metal interconnection;
the upper antenna board is made by a planar circuit/package process;
the first chipset is arranged on the upper surface of the lower chip carrier board, and the second chipset is arranged on the lower surface of the lower chip carrier board.

8. The three-dimensional heterogeneous integrated millimeter-wave system package structure according to claim 7, wherein the lower surfaces of the first chips are provided with solder balls/bumps which are connected to the upper RDL, the upper surfaces of the second chips are provided with solder balls/bumps which are connected to the lower RDL, the lower surfaces of the second chips are provided with tooth heat sink for heat dissipation, the bottom of the millimeter-wave system package structure is connected with a printed circuit board (PCB) board, and the PCB board is provided with an open cavity for accommodating the tooth heat sink.

9. The three-dimensional heterogeneous integrated millimeter-wave system package structure according to claim 7, wherein the lower surface of the upper antenna board is provided with a groove, the first chipset is arranged in the groove, the lower surfaces of the first chips are the surfaces with active devices of the first chips, the lower surfaces of the first chips are provided with solder balls/bumps, the upper surfaces of the second chips are the surfaces with active devices of the second chips, and the upper surfaces of the second chips are provided with metalized vias and solder balls/bumps which are connected with the solder balls/bumps arranged on the lower surfaces of the first chips.

10. The three-dimensional heterogeneous integrated millimeter-wave system package structure according to claim 9, wherein one first chip is arranged and is a silicon-based radio frequency control chip, and correspondingly, one groove is arranged and located in the central position of the lower surface of the upper antenna board; and a plurality of second chips are arranged and are compound semiconductor radio frequency front-end chips.

11. The three-dimensional heterogeneous integrated millimeter-wave system package structure according to claim 9, wherein a plurality of first chips are arranged, comprising one silicon-based radio frequency control chip and a plurality of PMUs, and correspondingly, a plurality of grooves are arranged, wherein one groove is located in the central position of the lower surface of the upper antenna board for arranging one silicon-based radio frequency control chip, and the remaining grooves are used for arranging the PMUs and arranged around the silicon-based radio frequency control chip.

12. The three-dimensional heterogeneous integrated millimeter-wave system package structure according to claim 7, wherein the upper surface of the lower chip carrier board is provided with SMDs; and the lower chip carrier board is made by superimposing a plurality of different material layers.

13. The three-dimensional heterogeneous integrated millimeter-wave system package structure according to claim 7, wherein the first chips are silicon-based radio frequency control chips which are fabricated by a CMOS, SiGe BiCMOS or SOI technology; and the second chips are compound semiconductor radio frequency front-end chips which are fabricated by a GaAs, GaN or InP technology.

14. A three-dimensional heterogeneous integrated millimeter-wave system package structure, composed of an upper antenna board and a lower chip carrier board; a gap is arranged between the upper antenna board and the lower chip carrier board which are connected through solder balls; and the upper antenna board has an integrated structure with an AiP and a feed network arranged inside, the lower chip carrier board has a modular structure provided with a first chipset and a second chipset, the second chipset is located under the first chipset, the first chipset comprises a plurality of first chips, the second chipset comprises a plurality of second chips, the first chips and the second chips are heterogeneous chips fabricated by different semiconductor technologies, and the surfaces with active devices of the first chips and the second chips are face-to-face but are staggered in the vertical direction;
the lower chip carrier board is composed of an upper RDL, a core layer and a lower RDL stacked successively from top to bottom; and the upper antenna board is provided with a plurality of vertical metalized vias and connected to the upper RDL through solder balls/bumps, and the upper RDL, the core layer and the lower RDL are respectively provided with a plurality of metalized vias through which any-layer interconnection is realized;
the first chips are electrically connected with the second chips through the metalized vias and/or solder balls/bumps by means of metal interconnection;
the upper antenna board is made by a planar circuit/package process;
the first chipset is embedded in the core layer of the lower chip carrier board, and the second chipset is arranged on the lower surface of the lower chip carrier board.

15. The three-dimensional heterogeneous integrated millimeter-wave system package structure according to claim 14, wherein the upper surfaces of the second chips are provided with solder balls/bumps which are connected to the lower RDL, and the first chips and the second chips are electrically connected through the solder balls/bumps directly; and the lower surfaces of the second chips are provided with tooth heat sink for heat dissipation, the bottom of the millimeter-wave system package structure is connected with a PCB board, and the PCB board is provided with an open cavity for accommodating the tooth heat sink.

16. The three-dimensional heterogeneous integrated millimeter-wave system package structure according to claim 14, wherein the upper surface of the lower chip carrier board is provided with SMDs; and the lower chip carrier board is made by superimposing a plurality of different material layers.

17. The three-dimensional heterogeneous integrated millimeter-wave system package structure according to claim 14, wherein the first chips are silicon-based radio frequency control chips which are fabricated by a CMOS, SiGe BiCMOS or SOI technology; and the second chips are compound semiconductor radio frequency front-end chips which are fabricated by a GaAs, GaN or InP technology.
